(19) United States
(12) Patent Application Publication
(10) Pub. No.: US 2025/0174581 A1
(43) Pub. Date: May 29, 2025

(54) SEMICONDUCTOR DEVICE

(71) Applicant: NANYA TECHNOLOGY CORPORATION, New Taipei city (TW)

(72) Inventor: Da-Zen CHUANG, Taipei City (TW)

(21) Appl. No.: 18/519,044

(22) Filed: Nov. 26, 2023

(51) Int. Cl. H01L 23/64; H01L 23/498; H01L 25/065; H10B 80/00

(52) U.S. Cl. CPC H01L 23/642; H01L 23/49838; H01L 25/0655; H10B 80/00

(57) ABSTRACT

The present disclosure provides a semiconductor device. The semiconductor device includes a package substrate, an interposer layer, an oxide layer, and a top conductive layer. The interposer layer is disposed on the package substrate. The interposer layer includes a plurality of regular capacitor arrays and a plurality of redundant capacitor arrays. The regular capacitor arrays are located in the interposer layer, wherein each regular capacitor array includes a plurality of regular capacitors. Each regular capacitor includes a lower electrode, a dielectric layer, and an upper electrode, wherein the dielectric layer is surrounded by the lower electrode, and the upper electrode is surrounded by the dielectric layer. The redundant capacitor arrays are located in the interposer layer and located around the regular capacitor arrays, wherein each redundant capacitor array includes a plurality of redundant capacitors.

### BACKGROUND

### Field of Invention

The present invention relates to semiconductor device. More particularly, the present invention relates to semiconductor device that include redundant capacitor arrays.

### Description of Related Art

Si interposer layer has been widely used for advanced 2.5D and/or 3D IC manufacturing for artificial intelligence (AI) related applications. As the function of 2.5D and/or 3D integrated circuit (IC) devices advances, capacitors are added to the Si interposer layer to improve power integrity (PI) and signal integrity (SI), especially for devices operating at higher frequencies.

However, the failure of even a single capacitor may jeopardize the accuracy of the final target capacitors and impact the overall yield. Therefore, how to resolve the issue described above is an important development item for semiconductor devices.

### SUMMARY

In accordance with an aspect of the present disclosure, a semiconductor device is provided. The semiconductor device includes a package substrate, an interposer layer, an oxide layer, and a top conductive layer. The interposer layer is disposed on the package substrate. The interposer layer includes a plurality of regular capacitor arrays and a plurality of redundant capacitor arrays. The regular capacitor arrays are located in the interposer layer, wherein each regular capacitor array includes a plurality of regular capacitors. Each regular capacitor includes a lower electrode, a dielectric layer, and an upper electrode, wherein the dielectric layer is surrounded by the lower electrode, and the upper electrode is surrounded by the dielectric layer. The redundant capacitor arrays are located in the interposer layer and located around the regular capacitor arrays, wherein each redundant capacitor array includes a plurality of redundant capacitors. Each redundant capacitor includes a lower electrode, a dielectric layer, and an upper electrode, wherein the dielectric layer is surrounded by the lower electrode, and the upper electrode is surrounded by the dielectric layer. The oxide layer is located on the interposer layer, wherein the oxide layer isolates the upper electrode of each regular capacitor and the upper electrode of each redundant capacitor. The top conductive layer is located on the oxide layer, wherein the top conductive layer connects the upper electrode of each regular capacitor and the upper electrode of the redundant capacitor.

According to some embodiments of the present disclosure, the semiconductor device further includes a first memory chiplet and a second memory chiplet, wherein the first memory chiplet is disposed on the top conductive layer, and the second memory chiplet is disposed on the top conductive layer and the second memory chiplet is adjacent to the first memory chiplet.

According to some embodiments of the present disclosure, the semiconductor device further includes a first memory chiplet and a second memory chiplet, wherein the first memory chiplet is disposed on the top conductive layer, and the second memory chiplet is disposed on the first memory chiplet, and overlap with the first memory chiplet.

According to some embodiments of the present disclosure, wherein the plurality of regular capacitor arrays are connected in series.

According to some embodiments of the present disclosure, wherein the plurality of regular capacitor arrays are connected in parallel.

According to some embodiments of the present disclosure, wherein the plurality of redundant capacitor arrays are connected in series.

According to some embodiments of the present disclosure, wherein the plurality of redundant capacitor arrays are connected in parallel.

According to some embodiments of the present disclosure, the plurality of regular capacitor arrays and the plurality of redundant capacitor arrays are connected in series.

According to some embodiments of the present disclosure, the plurality of regular capacitor arrays and the plurality of redundant capacitor arrays are connected in parallel.

According to some embodiments of the present disclosure, one of the redundant capacitor arrays is connected to one of the regular capacitor arrays.

According to some embodiments of the present disclosure, the plurality of redundant capacitor arrays includes a plurality of first redundant capacitor arrays and a plurality of second redundant capacitor arrays. The first redundant capacitor arrays connect to each other. The second redundant capacitor arrays connect to each other, wherein the second redundant capacitor arrays are separated from the first redundant capacitor arrays.

According to some embodiments of the present disclosure, wherein the interposer layer includes an N-well region, and an N+ region disposed in the N-well region and surrounding the plurality of redundant capacitor arrays and the plurality of redundant capacitor arrays.

In accordance with an aspect of the present disclosure, a semiconductor device is provided. The semiconductor device includes a package substrate, an interposer layer, an oxide layer, a bottom conductive layer, and a top conductive layer. The interposer layer is disposed on the package substrate. The oxide layer is located on the interposer layer, wherein the oxide layer includes a plurality of regular capacitor arrays, a plurality of redundant capacitor arrays. The plurality of regular capacitor arrays located on the interposer layer, wherein each regular capacitor array comprises a lower electrode comprising two vertical portion and a lateral portion; a dielectric layer comprising two vertical portion and a lateral portion; and an upper electrode surrounded by the dielectric layer. The plurality of redundant capacitor arrays located in the interposer layer and located around the plurality of regular capacitor arrays, wherein each regular capacitor array comprises: a lower electrode comprising two vertical portion and a lateral portion; a dielectric layer comprising two vertical portion and a lateral portion; and an upper electrode surrounded by the dielectric layer. The bottom conductive layer located between the interposer layer and the oxide layer. The top conductive layer located on the oxide layer.

According to some embodiments of the present disclosure, wherein each regular capacitor array and each redundant capacitor array both comprise a capacitor I, a capacitor II, and a capacitor III, wherein the capacitor II is disposed between the capacitor I and the capacitor III.

According to some embodiments of the present disclosure, wherein the capacitor I includes an upper electrode the dielectric layer surrounding the upper electrode, and a portion of the bottom conductive layer, wherein the dielectric layer contact with the portion of the bottom conductive layer.

According to some embodiments of the present disclosure, wherein the capacitor II includes the upper electrode, the vertical portion of the dielectric layer, and the vertical portion of the lower electrode, wherein the dielectric layer is disposed between the upper electrode and the lower electrode.

According to some embodiments of the present disclosure, wherein the capacitor III includes the upper electrode, the lateral portion of the dielectric layer, and the lateral portion of the lower electrode, wherein the dielectric layer is disposed between the upper electrode and the lower electrode.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view schematic diagram of the semiconductor device, in accordance with some embodiments;

FIG. 2 is a top view schematic diagram of the relationship between the regular capacitor arrays and the redundant capacitor arrays, in accordance with some embodiments;

FIG. 3 is a top view schematic diagram of the relationship between the regular capacitor arrays and the redundant capacitor arrays, in accordance with other embodiments;

FIG. 4 is a cross-sectional view schematic diagram of the semiconductor device, in accordance with some embodiments;

FIG. 5 is a cross-sectional view schematic diagram of the semiconductor device, in accordance with other embodiments;

FIG. 6A is a cross-sectional view schematic diagram of the semiconductor device, in accordance with some embodiments;

FIG. 6B is a partial enlarged cross-sectional view schematic diagram of FIG. 6A, in accordance with some embodiments;

FIG. 6C is an equivalent circuit diagram of FIG. 6B, in accordance with some embodiments;

FIG. 7 is a cross-sectional view schematic diagram of the semiconductor device of FIG. 6, in accordance with some embodiments;

FIG. 8 is a cross-sectional view schematic diagram of the semiconductor device of FIG. 6, in accordance with other embodiments.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

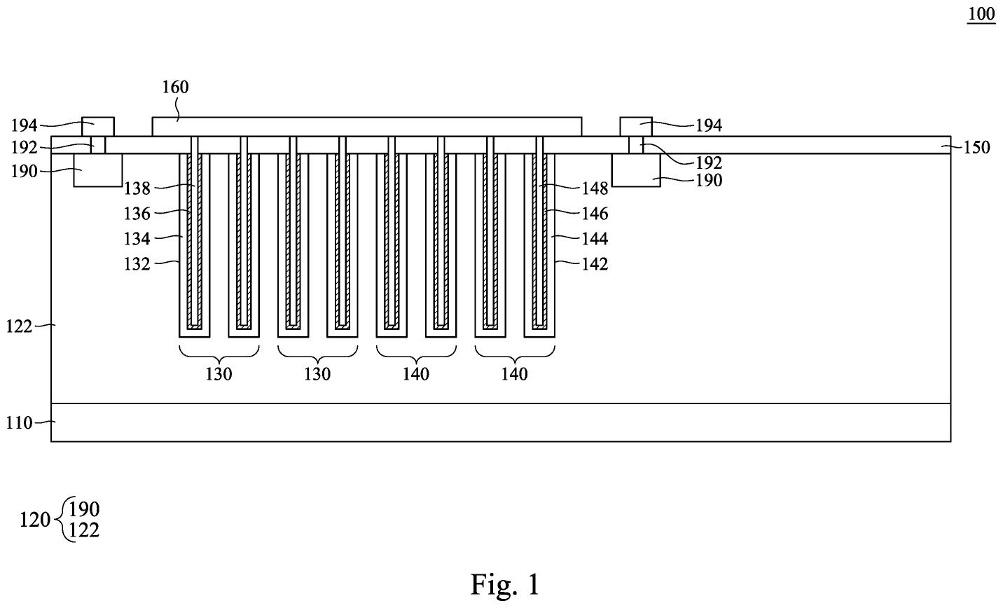

FIG. 1 is a cross-sectional view schematic diagram of the semiconductor device 100, in accordance with some embodiments. The semiconductor device 100 can be applied in an integrated circuit (IC) or a part thereof, such as a logic circuit, a resistor, a capacitor, an inductor, a memory (such as a dynamic random access memory (DRAM)), and the like. It should be understood that some elements of the semiconductor device 100 are not shown in FIGS. 1-10 to simplify the drawings, and that additional elements may be included in other embodiments of the semiconductor device 100.

Referring to FIG. 1, the semiconductor device 100 may include a package substrate 110, an interposer layer 120, a plurality of regular capacitor arrays 130, a plurality of redundant capacitor arrays 140, an oxide layer 150, and a top conductive layer 160. The interposer layer 120 is disposed on a package substrate 110. In some embodiments, the interposer layer 120 may include silicon-based material. In some embodiments, the interposer layer 120 may include an N-well region 122 and an N+ region 190. In some embodiments, the interposer layer 120 includes through substrate vias (TSV) (not shown). The interposer layer 120 and the packaged substrate 110 are electrically coupled through the TSV.

In some embodiments, the packaged substrate 110 may be a printed-circuit board, a ceramic, an organic, glass, and/or semiconductor material or structure. In some embodiments, the packaged substrate 110 provides a backplane with power, ground, control, monitoring, etc. The packaged substrate 110 may include a plurality of solder balls (not shown) formed on the packaged substrate 110 for routing signals to route electrical signals to other electrical devices (e.g., motherboard or other chipset).

The plurality of regular capacitor arrays 130 and the plurality of redundant capacitor arrays 140 is disposed in the interposer layer 120. Each regular capacitor array 130 may include a plurality of regular capacitors 132, wherein each regular capacitor 132 may include a lower electrode 134, a dielectric layer 136, and an upper electrode 138. The dielectric layer 136 may be surrounded by the lower electrode 134, and the upper electrode 138 may be surrounded by the dielectric layer 136. In some embodiments, the dielectric layer 136 and the lower electrode 134 both have a U-shape cross-sectional profile. In some embodiments, the lower electrode 134 and the upper electrode 138 may include conductive material such as metal, metal alloy, metal nitride, or the like. In some embodiments, the lower electrode 134 and the upper electrode 138 may include tungsten. The dielectric layer 136 include a dielectric material, such as tetraethylorthosilicate (TEOS), a low-k dielectric material, doped silicon oxide (e.g., borophosphosilicate glass (BPSG), fused silica glass (FSG), phosphosilicate glass (PSG), boron doped silicon glass (BSG), etc.), and/or other suitable dielectric materials.

Each redundant capacitor array 140 may include a plurality of redundant capacitors 142, wherein each redundant capacitor 142 may include a lower electrode 144, a dielectric layer 146, and an upper electrode 148. The dielectric layer 146 may be surrounded by the lower electrode 144, and the upper electrode 148 may be surrounded by the dielectric layer 146. In some embodiments, the dielectric layer 146 and the lower electrode 144 both have a U-shape cross-sectional profile. In some embodiments, the lower electrode 144 and the upper electrode 148 may include conductive material such as metal, metal alloy, metal nitride, or the like. In some embodiments, the lower electrode 144 and the upper electrode 148 may include tungsten. The dielectric layer 146 includes a dielectric material, such as tetraethylorthosilicate (TEOS), a low-k dielectric material, silicon oxide, and/or other suitable dielectric materials.

The oxide layer 150 is disposed on the interposer layer 120. The oxide layer 150 may isolate the upper electrode 138 of each regular capacitor 132 and the upper electrode 148 of each redundant capacitor 142. In some embodiments, the oxide layer 150 may include silicon oxide (SiO₂), zirconium oxide, titanium oxide, aluminum oxide (Al₂O₃), hafnium oxide, or combinations thereof.

The top conductive layer 160 is disposed on the oxide layer 150. The top conductive layer 160 may connect the upper electrode 138 of each regular capacitor 132 and the upper electrode 148 of each redundant capacitor 142. In some embodiments, the top conductive layer 160 may include conductive material such as metal, metal alloy, metal nitride, or the like. In some embodiments, the top conductive layer 160, the upper electrode 138, the upper electrode 148 may include same materials. In some embodiments, the top conductive layer 160, the upper electrode 138, the upper electrode 148 may include different materials.

The N+ region 190 is disposed in the N-well region 122 and surrounding the regular capacitor arrays 130 and the redundant capacitor arrays 140. The N+ region 190 is coupled to a top electrode 194 by an upper electrode 192. The upper electrode 192 may be disposed in the oxide layer 150 and the top electrode 194 may be disposed on the oxide layer 150. In some embodiments, the upper electrode 192, the upper electrode 138, and the upper electrode 148 may include same material(s). In some embodiments, the top electrode 194 and the top electrode 160 may include same material(s).

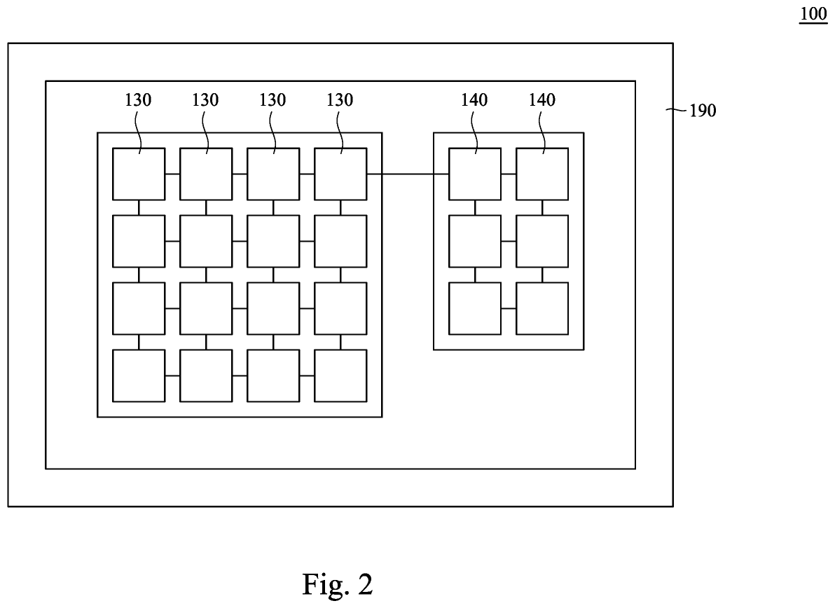

FIG. 2 is a top view schematic diagram of the relationship between the regular capacitor arrays 130 and the redundant capacitor arrays 140. Referring to FIG. 2, one of the redundant capacitor arrays 140 connected to one of the regular capacitor arrays 130. As shown, the N+ region 190 surrounds the regular capacitor arrays 130 and the redundant capacitor arrays 140. In some embodiments, one of the redundant capacitor arrays 140 and one of the regular capacitor arrays 130 may be connected in series. In some embodiments, one of the redundant capacitor arrays 140 and one of the regular capacitor arrays 130 may be connected in parallel. In some embodiments, the plurality of regular capacitor arrays 130 may be connected to each other in series. In some embodiments, the plurality of regular capacitor arrays 130 may be connected to each other in parallel. In some embodiments, the plurality of redundant capacitor arrays 140 may be connected to each other in series. In some embodiments, the plurality of redundant capacitor arrays 140 may be connected to each other in parallel. The redundant capacitor arrays 140 may be used for the replacement and repair the damaged regular capacitor arrays 130, or for the adjustment of the capacitor value. The regular capacitors 132 and the redundant capacitor 142 are used for reducing signal noise and reducing leakage between the IC devices.

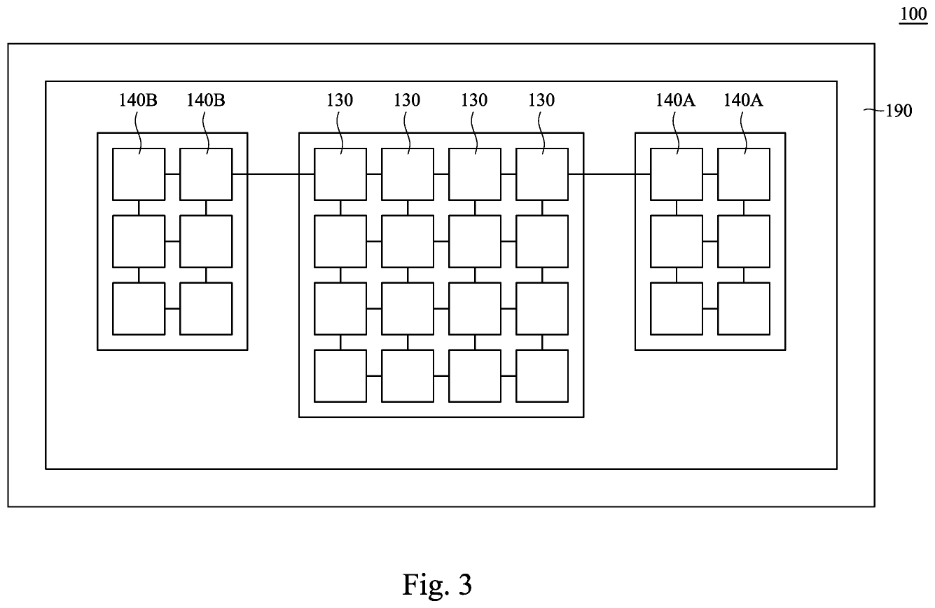

FIG. 3 is a top view schematic diagram of the relationship between the regular capacitor arrays 130, the first redundant capacitor arrays 140A, and the second redundant capacitor arrays 140B, in accordance with other embodiments. Referring to FIG. 3, the plurality of redundant capacitor arrays 140 may include a plurality of first redundant capacitor arrays 140A and a plurality of second redundant capacitor arrays 140B. The plurality of first redundant capacitor arrays 140A may connect to each other. The plurality of second redundant capacitor arrays 140B may connect to each other. The plurality of first redundant capacitor arrays 140A are separated from the plurality of second redundant capacitor arrays 140B. One of the first redundant capacitor arrays 140A connected to one of the regular capacitor arrays 130. One of the second redundant capacitor arrays 140B connected to one of the regular capacitor arrays 130. In some embodiments, more redundant capacitor arrays may also be included, and connected to regular capacitor arrays 130 respectively.

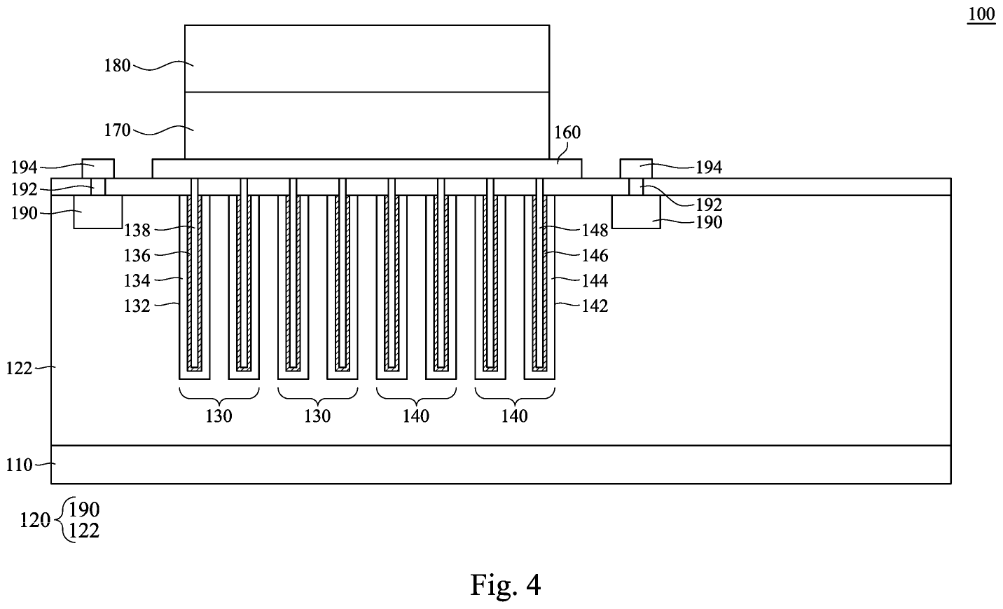

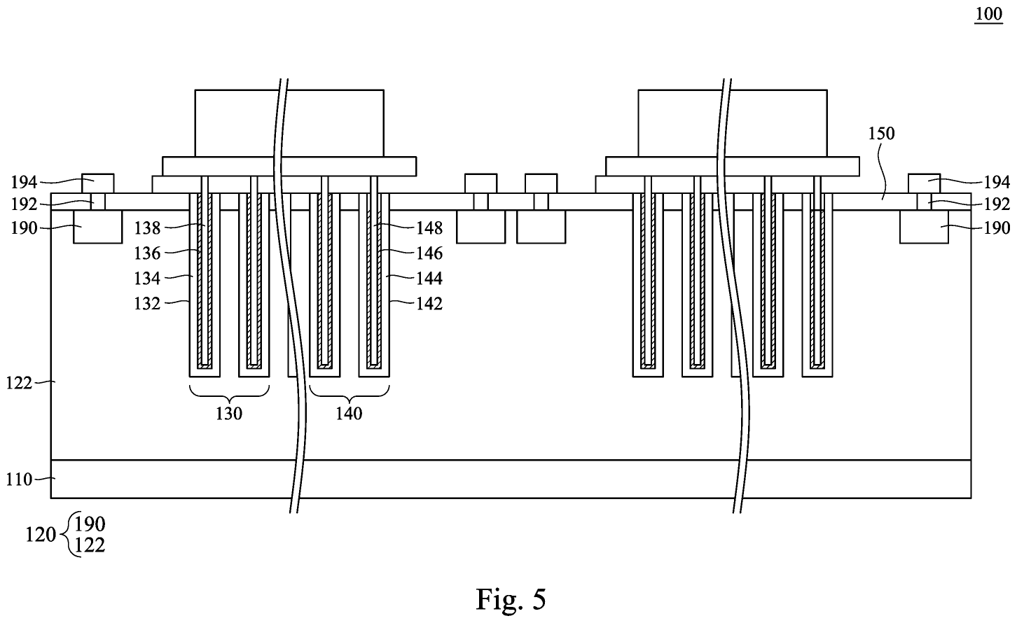

Referring to FIG. 4 and FIG. 5, the semiconductor device 100 may further include a first memory chiplet 170 and a second memory chiplet 180. As shown in FIG. 4, the first memory chiplet is disposed on the top conductive layer 160, and the second memory chiplet 180 may be disposed on the first memory chiplet 170. In some embodiments, the second memory chiplet 180 overlaps with the first memory chiplet 170. The first memory chiplet 170 is electrically connected to the top conductive layer 160, and the second memory chiplet 180 is electrically connected to the first memory chiplet 170.

As shown in FIG. 5, the first memory chiplet 170 is disposed on the top conductive layer 160, and the second memory chiplet 180 is disposed on the top conductive layer 160, wherein the first memory chiplet 170 is adjacent to the second memory chiplet 180. The first memory chiplet 170 is electrically connected to the top conductive layer 160, and the second memory chiplet 180 is electrically connected to the top conductive layer 160, respectively. In some embodiments, the first memory chiplet 170 directly contact to the top conductive layer 160, and the second memory chiplet 180 directly contact to the top conductive layer 160. In some embodiments, the first memory chiplet 170 and the second memory chiplet 180 are disposed on the same plane of the top conductive layer 160.

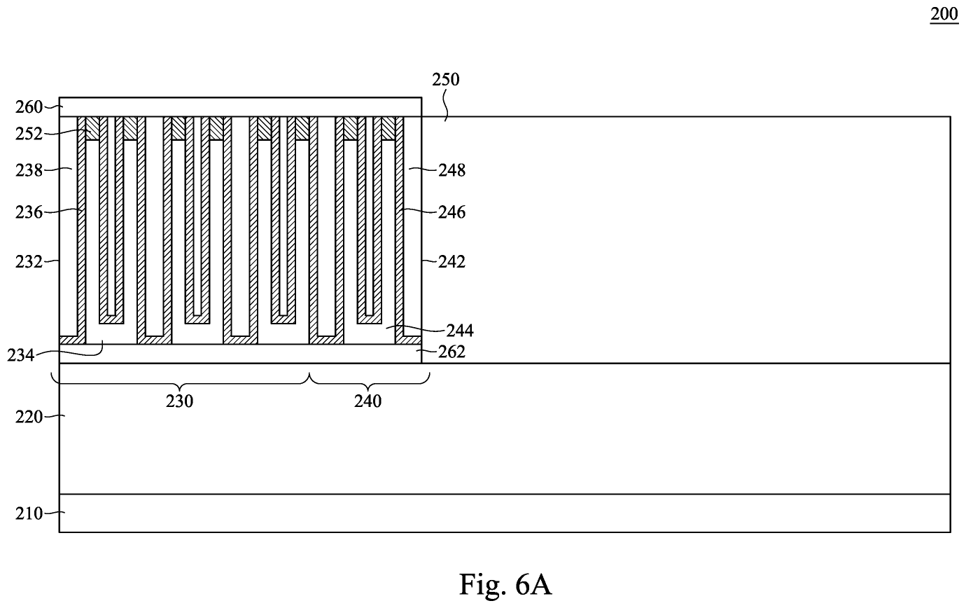

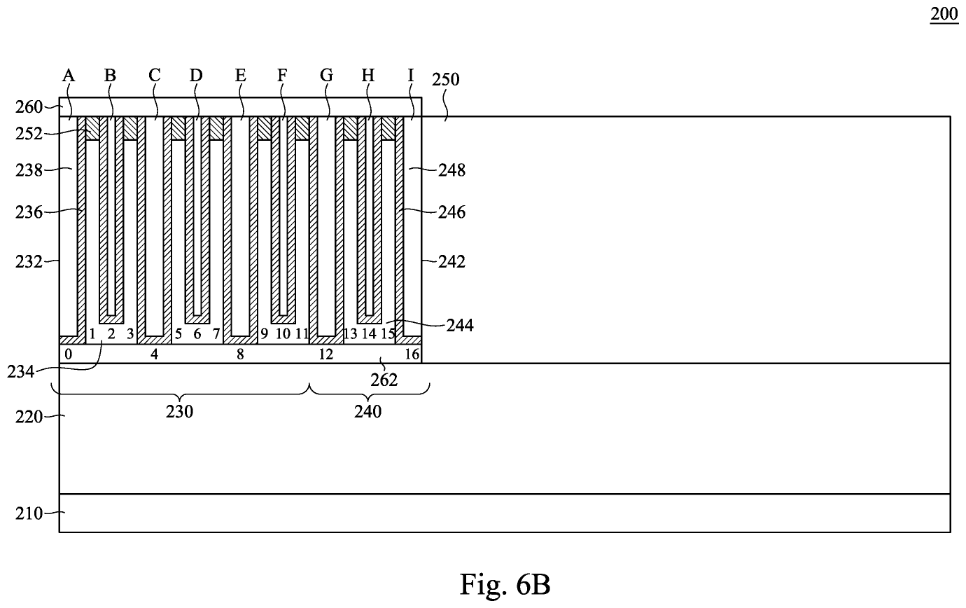

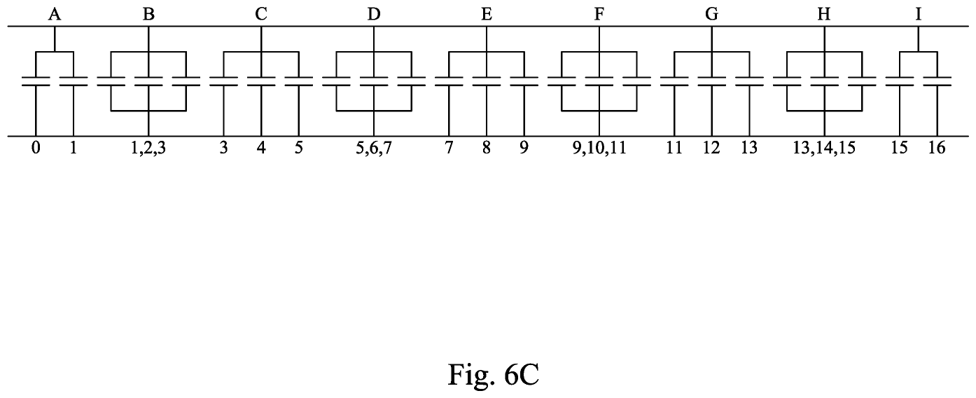

FIG. 6A is a cross-sectional view schematic diagram of the semiconductor device 200, in accordance with some embodiments. Referring to FIG. 6A, the semiconductor device 200 may include a package substrate 210, an interposer layer 220, a plurality of regular capacitor arrays 230, a plurality of redundant capacitor arrays 240, an oxide layer 250, a top conductive layer 260, and a bottom conductive layer 262. The interposer layer 220 is disposed on a package substrate 210.

The oxide layer 250 is disposed on the interposer layer 220. The oxide layer 250 may include a plurality of regular capacitor arrays 230 and a plurality of redundant capacitor arrays 240.

The plurality of regular capacitor arrays 230 and the plurality of redundant capacitor arrays 240 is disposed on the interposer layer 220. Each regular capacitor array 230 may include a plurality of regular capacitors 232, wherein each regular capacitor 232 may include a lower electrode 234, a dielectric layer 236, and an upper electrode 238. The upper electrode 238 is surrounded by the dielectric layer 236. In some embodiments, the dielectric layer 236 and the lower electrode 234 both have a U-shape cross-sectional profile. A cap layer 252 may dispose between the lower electrode 234 and the top electrode 260. In some embodiments, the cap layer 252 may include SiO₂. The cap layer 252 may insulate between the lower electrode 234 and the top electrode 260. In some embodiments, a portion of the dielectric layer 236 may contact with the bottom conductive layer 262. In some embodiments, the lower electrode 234 may contact with the top conductive layer 260 and the bottom conductive layer 262.

Each redundant capacitor array 240 may include a plurality of redundant capacitors 242, wherein each redundant capacitor 242 may include a lower electrode 244, a dielectric layer 246, and an upper electrode 248. The upper electrode 248 is surrounded by the dielectric layer 246. In some embodiments, the dielectric layer 246 and the lower electrode 244 both have a U-shape cross-sectional profile. A cap layer 252 may dispose between the lower electrode 244 and the top electrode 260. In some embodiments, the cap layer 252 may include SiO₂. The cap layer 252 may insulate between the lower electrode 244 and the top electrode 260. In some embodiments, a portion of the dielectric layer 246 may contact with the bottom conductive layer 262. In some embodiments, the lower electrode 244 may contact with the top conductive layer 260 and the bottom conductive layer 262.

The bottom conductive layer 262 located on the interposer layer 220, wherein the bottom conductive layer 262 connects the lower electrode 234 of each regular capacitor 230 and the lower electrode 244 of each redundant capacitor 240. The top conductive layer 260 located on the oxide layer, wherein the top conductive layer 260 connects the upper electrode 238 of each regular capacitor 232 and the upper electrode 248 of each redundant capacitor 242.

Referring to FIG. 6B and FIG. 6C, the regular capacitor 232 and the redundant capacitor 242 include three types of capacitors. For example, a capacitor I includes the upper electrode 238(A), the dielectric layer 236, and the bottom conductive layer 262(0), represented as (A, 0) below. As shown, (A, 0), (C, 4), (E, 8), (G, 12), and (I, 16) are capacitor I.

A capacitor II includes the upper electrode 238(B), the vertical portion of dielectric layer 236, and the vertical portion of lower electrode 234(1 or 3), represented as (B, 1) or (B, 3) below. As shown, (A, 1), (B, 1), (B, 3), (C, 3), (C, 5), (D, 5), (D, 7), (E, 7), (E, 9), (F, 9), (F, 11), (G, 11), (G, 13), (H, 13), (H, 15), and (I, 15) are capacitor II.

A capacitor III includes the upper electrode 238(B), the lateral portion of the dielectric layer 236, and lateral portion of the lower electrode 234(2), represented as (B, 2) below. As, shown, (B, 2), (D, 6), (F, 10),and (H, 14) are capacitor III.

The lower electrode 234(1, 2, and 3) shared the same upper electrode 238(B). The capacitor II is disposed between the capacitor I and the capacitor III. The regular capacitor 232 and the redundant capacitor 242 may be aligned in a sequence of “. . . capacitor I, capacitor II, capacitor II, capacitor III, capacitor II, capacitor II, capacitor I . . . ”.

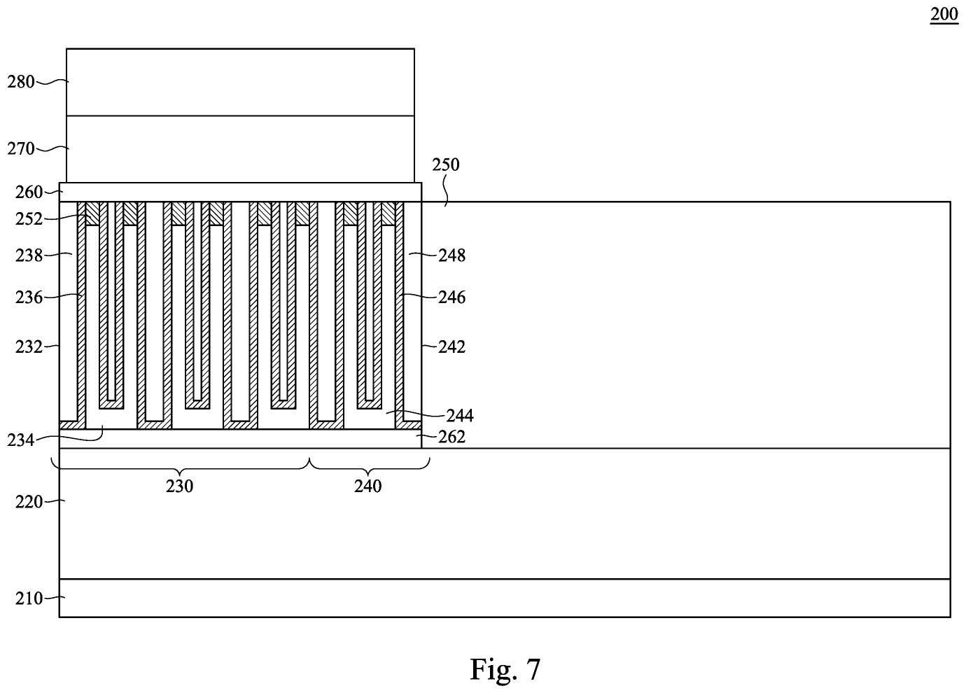

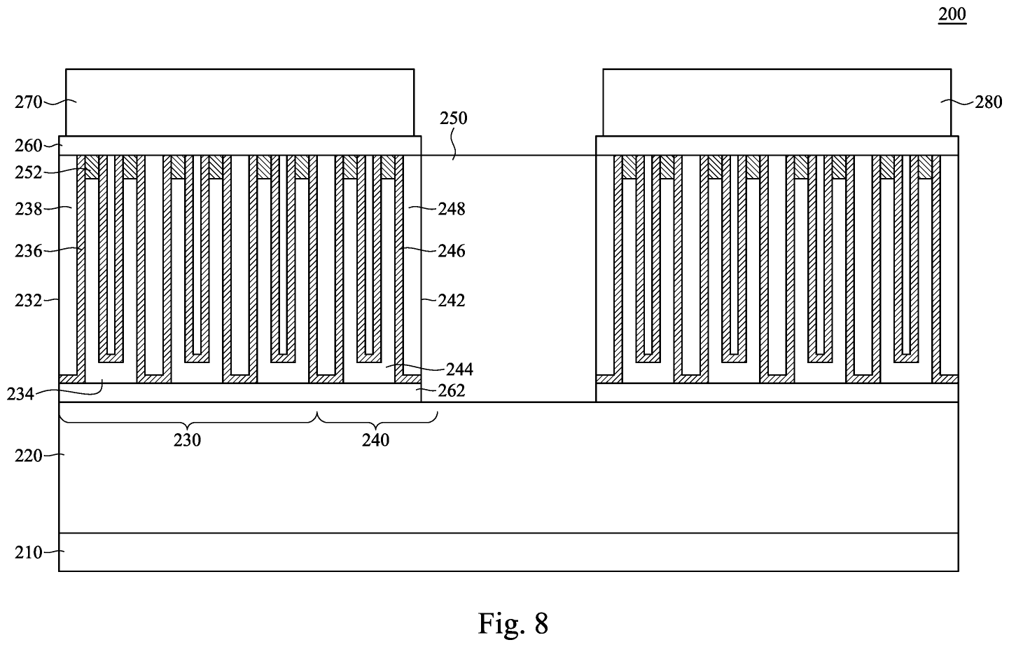

Referring to FIG. 7 and FIG. 8, the semiconductor device 200 may further include a first memory chiplet 270 and a second memory chiplet 280. As shown in FIG. 7, the first memory chiplet 270 is disposed on the top conductive layer 260, and the second memory chiplet 280 may be disposed on the first memory chiplet 270. In some embodiments, the second memory chiplet 280 overlaps with the first memory chiplet 270. The first memory chiplet 270 is electrically connected to the top conductive layer 260, and the second memory chiplet 280 is electrically connected to the first memory chiplet 270.

As shown in FIG. 8, the first memory chiplet 270 is disposed on the top conductive layer 260, and the second memory chiplet 280 is disposed on the top conductive layer 260, wherein the first memory chiplet 270 is adjacent to the second memory chiplet 280. The first memory chiplet 270 is electrically connected to the top conductive layer 260, and the second memory chiplet 280 is electrically connected to the top conductive layer 260, respectively. In some embodiments, the first memory chiplet 270 directly contact to the top conductive layer 260, and the second memory chiplet 280 directly contact to the top conductive layer 260. In some embodiments, the first memory chiplet 270 and the second memory chiplet 280 are disposed on the same plane of the top conductive layer 260.

According to the above embodiments of the present disclosure, the present disclosure provides a semiconductor device. With the semiconductor provided in the present disclosure, the novel capacitor scheme may improve the accuracy and the yield. The redundant capacitor arrays may replace and/or repair the damaged regular capacitor arrays, or may adjust the capacitor value. The regular capacitors and the redundant capacitor may reduce signal noise and reducing leakage between the integrated circuit devices.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor device, comprising:
a package substrate;
an interposer layer disposed on the package substrate, wherein the interposer layer comprises:
a plurality of regular capacitor arrays located in the interposer layer, wherein each regular capacitor array comprises a plurality of regular capacitors, wherein each regular capacitor comprises:
a lower electrode;
a dielectric layer surrounded by the lower electrode; and
an upper electrode surrounded by the dielectric layer;
a plurality of redundant capacitor arrays located in the interposer layer and located around the plurality of regular capacitor arrays, wherein each redundant capacitor array comprises a plurality of redundant capacitors, wherein each redundant capacitor comprises:
a lower electrode;
a dielectric layer surrounded by the lower electrode; and
an upper electrode surrounded by the dielectric layer;
an oxide layer located on the interposer layer, wherein the oxide layer isolates the upper electrode of each regular capacitor and the upper electrode of each redundant capacitor; and
a top conductive layer located on the oxide layer, wherein the top conductive layer connects the upper electrode of each regular capacitor and the upper electrode of the redundant capacitor.

2. The semiconductor device of claim 1, further comprising:
a first memory chiplet disposed on the top conductive layer; and
a second memory chiplet disposed on the top conductive layer, and adjacent to the first memory chiplet.

3. The semiconductor device of claim 1, further comprising:
a first memory chiplet disposed on the top conductive layer; and
a second memory chiplet disposed on the first memory die, and overlap with the first memory chiplet.

4. The semiconductor device of claim 1, wherein the plurality of regular capacitor arrays are connected in series.

5. The semiconductor device of claim 1, wherein the plurality of regular capacitor arrays are connected in parallel.

6. The semiconductor device of claim 1, wherein the plurality of redundant capacitor arrays are connected in series.

7. The semiconductor device of claim 1, wherein the plurality of redundant capacitor arrays are connected in parallel.

8. The semiconductor device of claim 1, wherein the plurality of regular capacitor arrays and the plurality of redundant capacitor arrays are connected in series.

9. The semiconductor device of claim 1, wherein the plurality of regular capacitor arrays and the plurality of redundant capacitor arrays are connected in parallel.

10. The semiconductor device of claim 1, wherein one of the redundant capacitor arrays is connected to one of the regular capacitor arrays.

11. The semiconductor device of claim 1, wherein the plurality of redundant capacitor arrays comprises:
a plurality of first redundant capacitor arrays connecting to each other; and
a plurality of second redundant capacitor arrays connecting to each other, wherein the plurality of second redundant capacitor arrays are separated from the plurality of first redundant capacitor arrays.

12. The semiconductor device of claim 1, wherein the interposer layer comprises:
an N-well region; and
an N+ region disposed in the N-well region and surrounding the plurality of redundant capacitor arrays and the plurality of redundant capacitor arrays.

13. A semiconductor device, comprising:
a package substrate;
an interposer layer disposed on the package substrate;
an oxide layer located on the interposer layer, wherein the oxide layer comprises:
a plurality of regular capacitor arrays located on the interposer layer, wherein each regular capacitor array comprises:
a lower electrode comprising two vertical portion and a lateral portion;
a dielectric layer comprising two vertical portion and a lateral portion; and
an upper electrode surrounded by the dielectric layer;
a plurality of redundant capacitor arrays located in the interposer layer and located around the plurality of regular capacitor arrays, wherein each regular capacitor array comprises:
a lower electrode comprising two vertical portion and a lateral portion;
a dielectric layer comprising two vertical portion and a lateral portion; and
an upper electrode surrounded by the dielectric layer;
a bottom conductive layer located between the interposer layer and the oxide layer; and
a top conductive layer located on the oxide layer.

14. The semiconductor device of claim 13, wherein each regular capacitor array and each redundant capacitor array both comprise a capacitor I, a capacitor II, and a capacitor III, wherein the capacitor II is disposed between the capacitor I and the capacitor III.

15. The semiconductor device of claim 14, wherein the capacitor I comprises:
the upper electrode;
the dielectric layer surrounding the upper electrode; and
a portion of the bottom conductive layer, wherein the dielectric layer contact with the portion of the bottom conductive layer.

16. The semiconductor device of claim 14, wherein the capacitor II comprises:
the upper electrode;
the vertical portion of the dielectric layer; and
the vertical portion of the lower electrode, wherein the dielectric layer is disposed between the upper electrode and the lower electrode.

17. The semiconductor device of claim 14, wherein the capacitor III comprises:
the upper electrode;
the lateral portion of the dielectric layer, and the lateral portion of the lower electrode, wherein the dielectric layer is disposed between the upper electrode and the lower electrode.
